(19) United States
(12) Patent Application Publication
(10) Pub. No.: US 2019/0107122 A1
(43) Pub. Date: Apr. 11, 2019

(54) SLIM PUMP STRUCTURE

(71) Applicant: ASIA VITAL COMPONENTS (CHINA) CO., LTD., Shenzhen (CN)

(72) Inventor: Meng Shen, Shenzhen (CN)

(21) Appl. No.: 15/725,290

(22) Filed: Oct. 5, 2017

(51) Int. Cl. F04D 29/58; F04D 13/02; F04D 29/22; H05K 7/20

(52) U.S. Cl. CPC F04D 29/586; F04D 13/02; F04D 1/00; H05K 7/20272; F04D 29/2261

(57) ABSTRACT

A slim pump structure includes a case, a rotor assembly, a flow guide plate, a stator assembly and an enclosure member. The case has a first side and a second side. The first side is formed with a pump chamber. A partitioning section partitions the pump chamber into a first chamber and a second chamber. A pivotal section upward extends from the second chamber. A center of the pivotal section is formed with a bearing hole. The second side is recessed to form a cavity corresponding to the pivotal section. Multiple axial ribs are formed on a circumference of the cavity at intervals. Each two adjacent ribs define a gap therebetween. The rotor assembly is received in the second chamber. The flow guide plate covers the second chamber so as to uncommunicate the second chamber from the first chamber. The stator assembly is correspondingly disposed on the case.

### BACKGROUND OF THE INVENTION

### 1. Field of the Invention

The present invention relates generally to a slim pump structure, and more particularly to a slim pump structure having a minified volume and greatly enhanced heat dissipation efficiency.

### 2. Description of the Related Art

It is known that the electronic apparatuses have higher and higher operation performance. As a result, in operation, the electronic components arranged in the electronic apparatuses will generate high heat. In general, a heat sink or a radiating fin assembly is disposed on the electronic components to enlarge the heat dissipation area and enhance the heat dissipation performance. However, the heat dissipation effect achieved by the heat sink or a radiating fin assembly is limited. Therefore, a conventional water-cooling device is often employed to enhance the heat dissipation effect.

The conventional water-cooling device contains a cooling liquid therein. The heat generated by a heat generation component (such as a processor or a graphics processing unit) is absorbed and heat-exchanged with the cooling liquid. A pump is disposed in the water-cooling device to circulate the cooling liquid. The water-cooling device is connected to a heat sink via multiple pipe bodies, whereby heat-exchange can take place between the heat sink and the water-cooling device via the circulated cooling liquid to quickly dissipate the heat of the heat generation components.

In the above conventional water-cooling device, the stator assembly is disposed outside the water-cooling device so as to prevent the stator assembly of the pump from being damaged due to contact with the cooling liquid. The rotor assembly for guiding the cooling liquid to circulate within the water-cooling device is disposed in the chamber of the water-cooling device. The magnetic member of the rotor assembly interacts with the corresponding silicon steel sheets of the stator assembly and is magnetized to operate via the case of the water-cooling device. Therefore, the case of the conventional water-cooling device must have a considerable thickness for having sufficient structural strength. Such structure will lead to a successively large volume of the water-cooling device. In addition, the thickness of the case of the water-cooling module will space the rotor assembly from the stator assembly to affect the operation efficiency of the pump. This will deteriorate the heat dissipation performance of the water-cooling module as a whole.

It is therefore tried by the applicant to provide a slim pump structure to eliminate the shortcomings existing in the conventional water-cooling device.

### SUMMARY OF THE INVENTION

It is therefore a primary object of the present invention to provide a slim pump structure, which has a slim structure.

It is a further object of the present invention to provide the above slim pump structure, the volume of which is greatly minified.

It is still a further object of the present invention to provide the above slim pump structure, which has greatly enhanced heat dissipation efficiency.

To achieve the above and other objects, the slim pump structure of the present invention includes a case, a rotor assembly, a flow guide plate, a stator assembly and an enclosure member. The case has a first side and a second side. The first side is formed with a pump chamber. A partitioning section partitions the pump chamber into a first chamber and a second chamber. A pivotal section upward extends from the second chamber. A center of the pivotal section is formed with a bearing hole. The second side is recessed to form a cavity corresponding to the pivotal section. Multiple axial ribs are formed on a circumference of the cavity at intervals. Each two adjacent ribs define a gap therebetween. The rotor assembly is received in the second chamber. The rotor assembly has a hub and a blade wheel. A rotary shaft downward extends from the hub. The rotary shaft is inserted in the bearing hole. A flow way is annularly formed on one side of the blade when in communication with the first and second chambers. The flow guide plate is disposed on an outer circumference of the rotor assembly to cover the second chamber so as to uncommunicate the second chamber from the first chamber. The stator assembly is received in the cavity. The stator assembly has multiple poles respectively correspondingly received in the gaps. The enclosure member is correspondingly disposed on the case to cover the case. The enclosure member and the flow guide plate define therebetween a communication chamber in communication with the first chamber and the flow way.

According to the above structural design of the present invention, when the slim pump structure operates, the working fluid first flows from the water inlet into the first chamber. Then, the working fluid will flow through the communication chamber between the flow guide plate and the enclosure member into the flow way of the rotor assembly. Then, the rotor assembly will rotate to throw out the working fluid to the second chamber. Finally, the working fluid will flow out from the water outlet to complete an internal circulation. The inner wall of the bearing hole is formed with multiple channels. Therefore, when the working fluid flows into the bearing hole, the channels will employ the working fluid as a medium to form a hydrodynamic bearing structure. Accordingly, the pump structure can be slimmed. In addition, the multiple axial ribs are formed on the circumference of the cavity at intervals and each two adjacent ribs define a gap therebetween to form a reinforcement structure. Under such circumstance, the thickness of the inner wall of the cavity can be extremely thinned. In this case, the poles of the stator assembly and the magnetic member disposed on the inner circumference of the rotor assembly can get closer to each other. This greatly enhances the interaction and magnetization between the poles and the magnetic member. Therefore, the operation efficiency of the rotor assembly is enhanced so that the heat dissipation efficiency can be increased as a whole.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1A is a perspective exploded view of a first embodiment of the slim pump structure of the present invention;

FIG. 1B is a perspective exploded view of the first embodiment of the slim pump structure of the present invention, seen from another angle;

FIG. 2A is a perspective assembled view of the first embodiment of the slim pump structure of the present invention;

FIG. 2B is a perspective sectional view of the first embodiment of the slim pump structure of the present invention;

FIG. 2C is another perspective sectional view of the first embodiment of the slim pump structure of the present invention;

FIG. 3 is a perspective generally exploded view of the first embodiment of the slim pump structure of the present invention;

FIG. 4A is an enlarged view of a part of the first embodiment of the slim pump structure of the present invention;

FIG. 4B is an enlarged view of a part of a second embodiment of the slim pump structure of the present invention;

FIG. 4C is an enlarged view of a part of a third embodiment of the slim pump structure of the present invention;

FIG. 4D is an enlarged view of a part of a fourth embodiment of the slim pump structure of the present invention; and

FIG. 5 is a perspective assembled view of a fifth embodiment of the slim pump structure of the present invention.

### DETAILED DESCRIPTION OF THE PREFERRED EMBODIMENTS

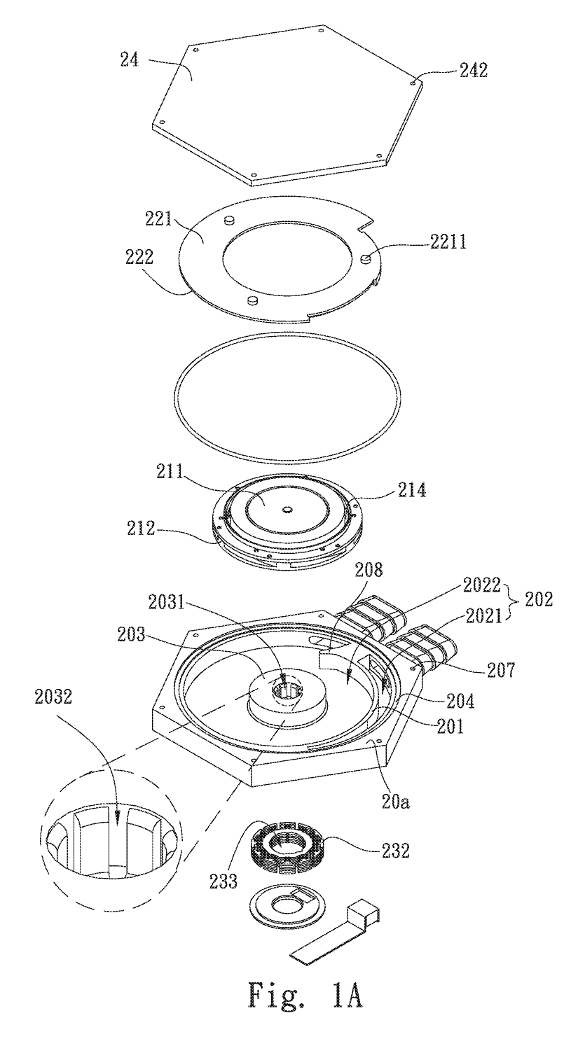

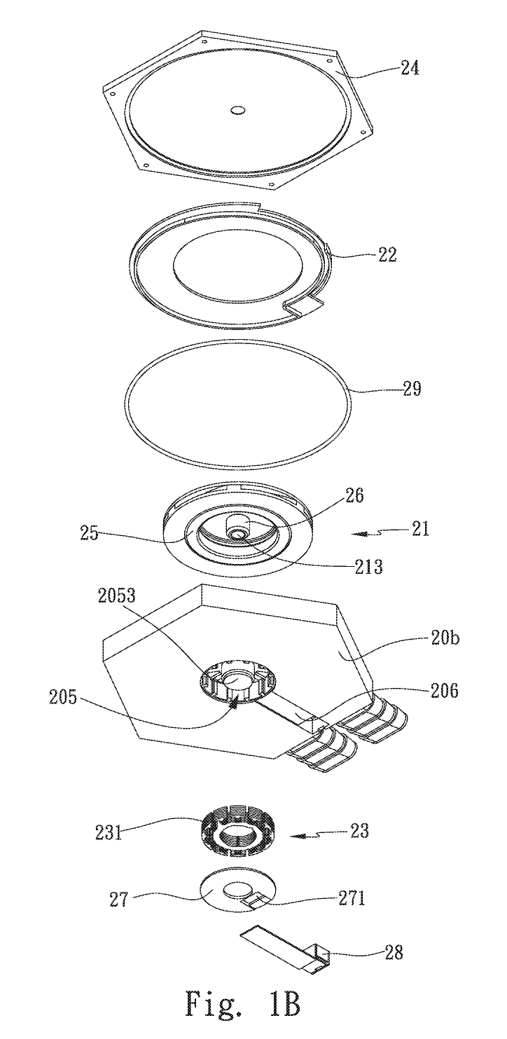

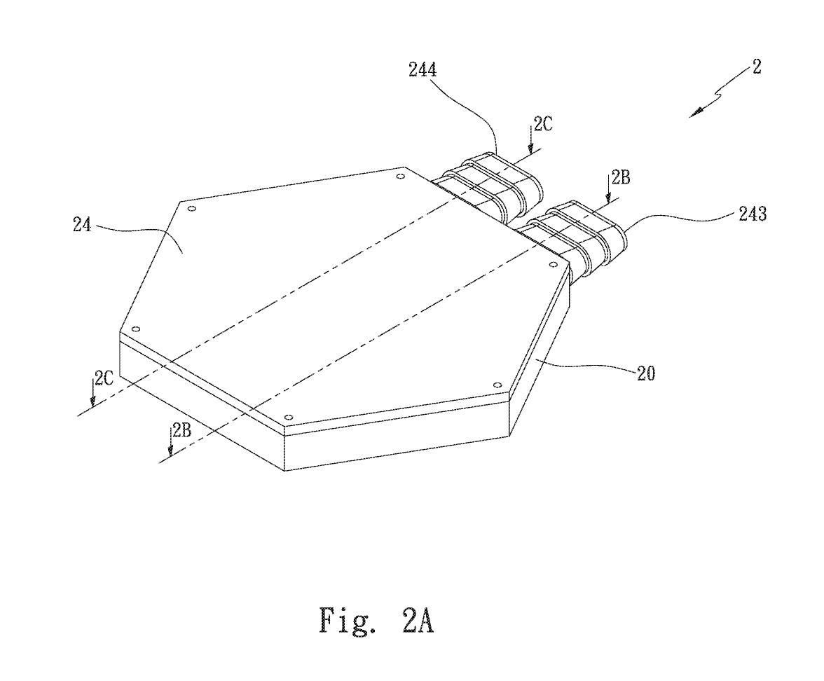

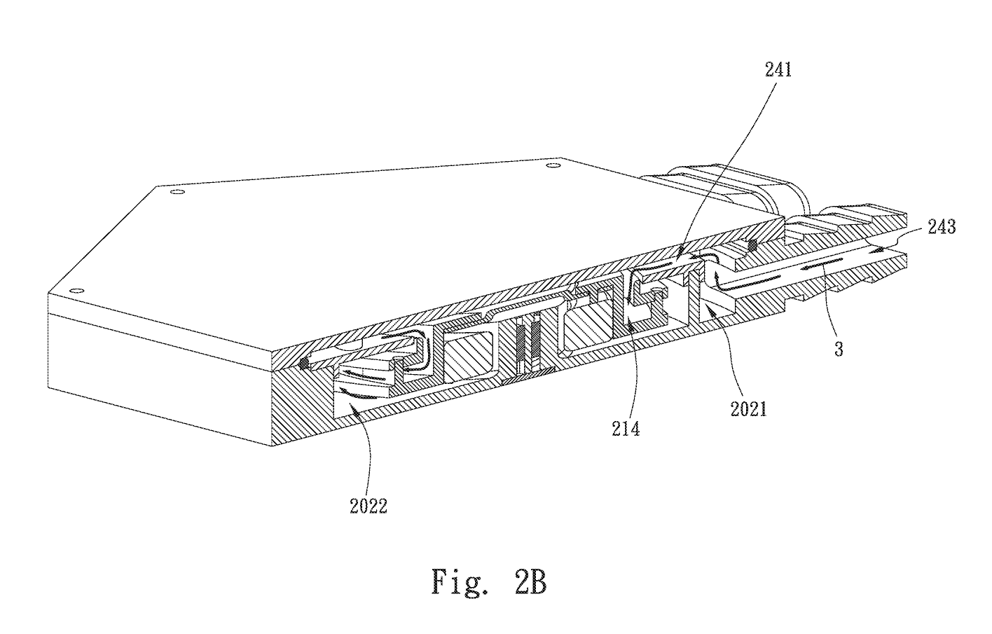

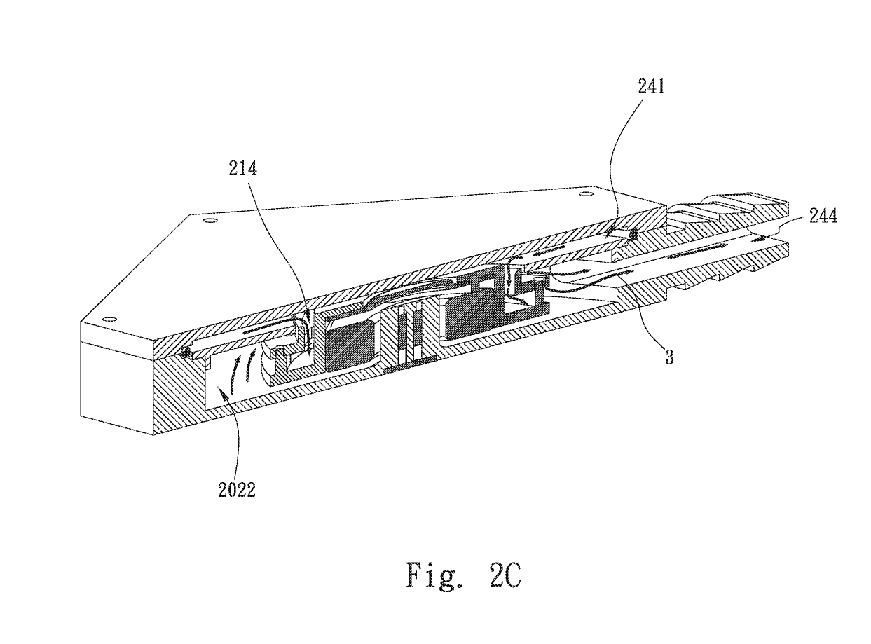

Please refer to FIGS. 1A, 1B, 2A, 2B and 2C. FIG. 1A is a perspective exploded view of a first embodiment of the slim pump structure of the present invention. FIG. 1B is a perspective exploded view of the first embodiment of the slim pump structure of the present invention, seen from another angle. FIG. 2A is a perspective assembled view of the first embodiment of the slim pump structure of the present invention. FIG. 2B is a perspective sectional view of the first embodiment of the slim pump structure of the present invention. FIG. 2C is another perspective sectional view of the first embodiment of the slim pump structure of the present invention. According to the first embodiment, the slim pump structure 2 of the present invention includes a case 20, a rotor assembly 21, a flow guide plate 22, a stator assembly 23 and an enclosure member 24. The case 20 has a first side 20a and a second side 20b. The first side 20a is formed with a pump chamber 202. A partitioning section 201 partitions the pump chamber 202 into a first chamber 2021 and a second chamber 2022. (The first and second chambers 2021, 2022 are positioned on the same horizontal face or the same vertical face). One end of the partitioning section 201 is formed with a tongue section 208. The tongue section 208 serves to guide a working fluid 3 contained in the second chamber 2022.

In this embodiment, the partitioning section 201, the tongue section 208, the pivotal section 203 and the fitting section 2053 are, but not limited to, integrally formed with the case 20. In other words, the case 20, the partitioning section 201, the tongue section 208, the pivotal section 203 and the fitting section 2053 can be alternatively separately manufactured according to a user's requirement and then assembled with each other. This can achieve the same effect.

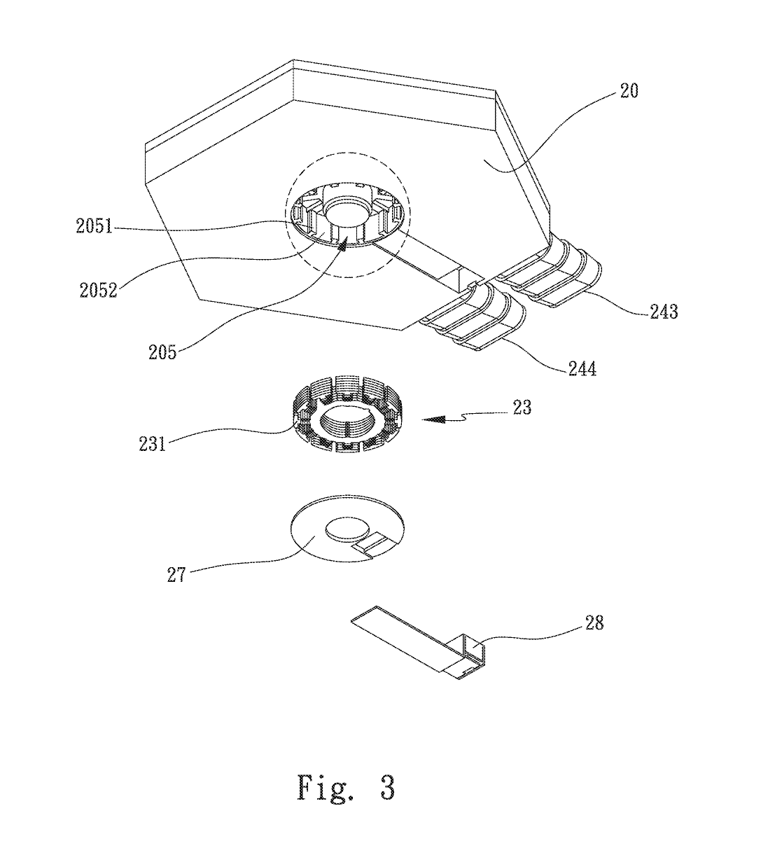

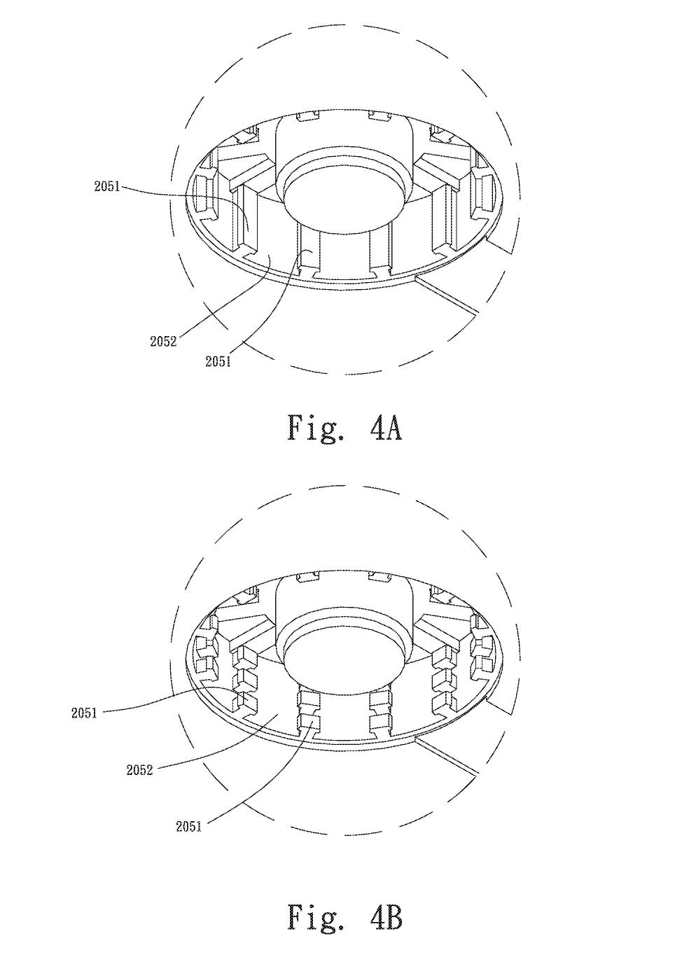

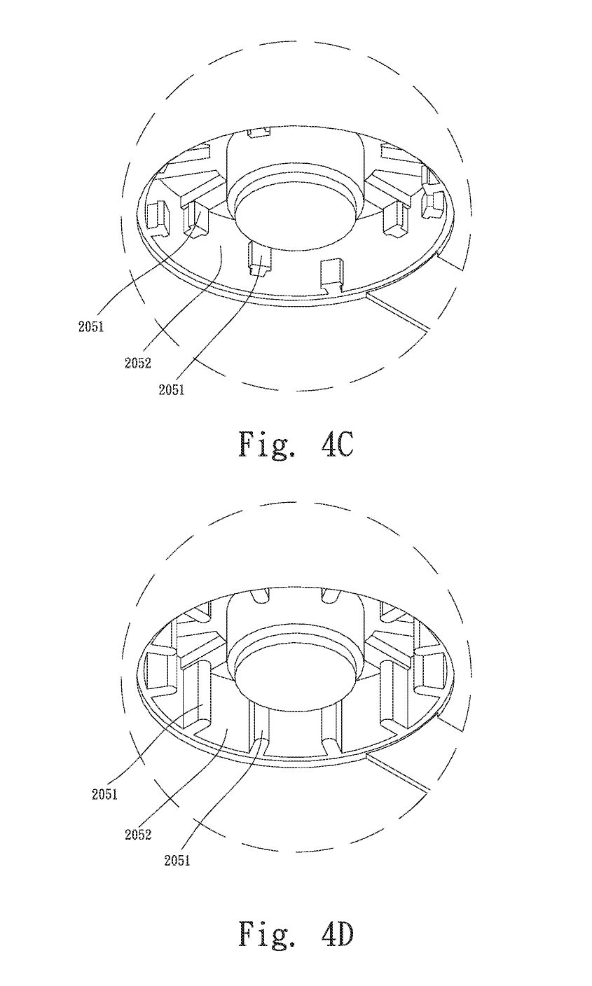

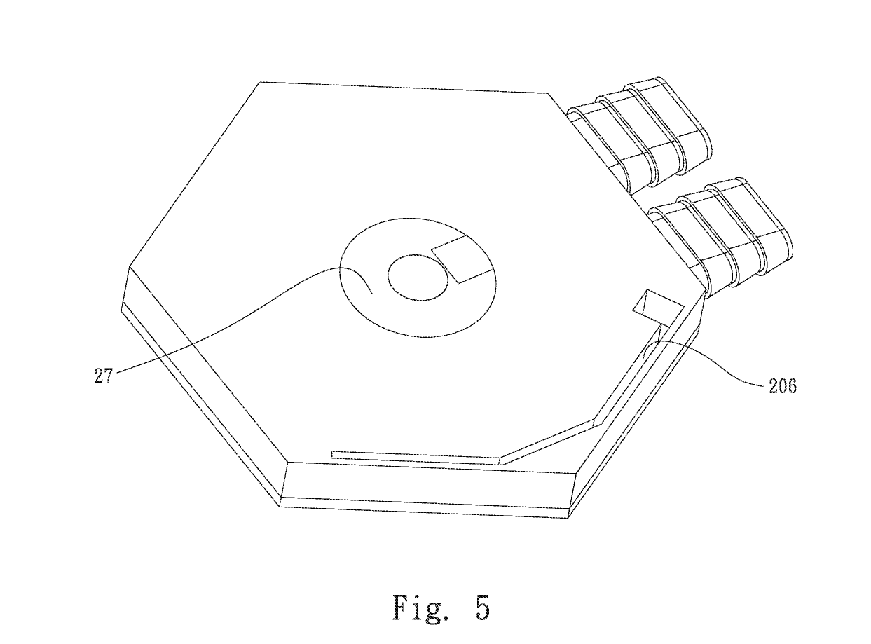

The pivotal section 203 upward extends from the second chamber 2022. The center of the pivotal section 203 is formed with a bearing hole 2031. The inner wall of the bearing hole 2031 is formed with multiple axial channels 2032 in communication with the second chamber 2022. A bearing 26 is disposed in the bearing hole 2031. The second side 20b is recessed to form a cavity 205 corresponding to the pivotal section 203 of the first side 20a. The fitting section 2053 protrudes from the center of the cavity 205 corresponding to the bearing hole 2031 of the first side 20a. Multiple axial ribs 2051 are formed on a circumference of the cavity 205 at intervals. Each two adjacent ribs 2051 define a gap 2052 therebetween (as shown in FIG. 3, which is a perspective generally exploded and relatively enlarged view showing the cavity 205 of the first embodiment of the present invention). Each rib 2051 can have a continuous form (as shown in FIG. 4A) or a discontinuous form (as shown in FIGS. 4B and 4C). Alternatively, each rib 2051 can have a (cross-sectional) configuration of T-shape, semicircular shape or any other shape (as shown in FIG. 4D). Certainly, the configuration of the rib 2051 will affect the configuration of the gap 2052 defined between the adjacent ribs 2051.

In addition, the first side 20a of the case 20 is further formed with a locating groove 204 along the outer circumference of the pump chamber 202. A leakproof member 29 is correspondingly disposed in the locating groove 204 to prevent the working fluid 3 from leaking outside in operation of the slim pump structure 2.

A water inlet 243 and a water outlet 244 are disposed on one side of the case 20. In this embodiment, the water inlet 243 and the water outlet 244 are, but not limited to, disposed on the same side of the case 20. In practice, the water inlet 243 and the water outlet 244 can be disposed in different positions according to the user's requirement. This will not affect the effect achieved by the present invention. The water inlet 243 communicates with the first chamber 2021. The water outlet 244 communicates with the second chamber 2022. In this embodiment, the water inlet 243 and the water outlet 244 have a flat form to minify the volume of the present invention and slim the present invention.

The rotor assembly 21 is received in the second chamber 2022. The rotor assembly 21 has a hub 211 and a blade wheel 212. A rotary shaft 213 downward extends from the hub 211. The rotary shaft 213 is passed through the bearing 26 and inserted in the bearing hole 2031. A flow way 214 is annularly formed on one side of the blade wheel 212. The flow way 214 communicates with the first and second chambers 2021, 2022. A magnetic member 25 is annularly disposed on inner circumference of the rotor assembly 21.

The flow guide plate 22 is disposed on the outer circumference of the rotor assembly 21 to fully cover the second chamber 2022 so as to uncommunicate the second chamber 2022 from the first chamber 2021. The flow guide plate 22 has a top face 221 and a bottom face 222. At least one raised body 2211 is formed on the top face 221 to abut against the enclosure member 24. The bottom face 222 covers the outer circumference of the rotor assembly 21.

The stator assembly 23 is received in the cavity 205. The stator assembly 23 is composed of multiple silicon steel sheets 231, which are stacked on each other. The center of the stator assembly 23 is formed with a perforation 233 for fitting on the fitting section 2053 of the cavity 205. The stator assembly 23 has multiple poles 232 respectively correspondingly received in the gaps 2052 of the cavity 205. In other words, the configuration of the gaps 2052 is varied with the configuration of the poles 232, whereby the poles 232 can be correspondingly received in the gaps 2052.

In addition, a stator cover 27 is correspondingly disposed on outer side of the stator assembly 23 to cover and fix the stator assembly 23 in the case 20. The stator cover 27 is formed with an opening 271. The second side 20b of the case 20 is formed with a receiving recess 206. A circuit board 28 is connected with the opening 271 and disposed in the receiving recess 206. In this embodiment, the receiving recess 206 is, but not limited to, formed on the second side 20b of the case 20 between the water inlet 243 and the water outlet 244 for illustration purposes. Alternatively, the receiving recess 206 can be selectively disposed along the periphery of the second side 20b of the case 20 (as shown in FIG. 5). This will not affect the effect of the present invention. Moreover, the circuit board 28 is, but not limited to, a flexible printed circuit board.

The enclosure member 24 is correspondingly disposed on the case 20 to cover the case 20. The enclosure member 24 and the flow guide plate 22 define therebetween a communication chamber 241 in communication with the first chamber 2021 and the flow way 214.

In this embodiment, the case 20 and the enclosure member 24 has a hexagonal configuration for illustration purposes. Each corner of the case 20 is formed with a connection section 207 and each corner of the enclosure member 24 is formed with an assembling section 242 for correspondingly assembling and connecting with the connection section 207. The case 20 and the enclosure member 24 can be connected by means of engagement, insertion or adhesion. Alternatively, the case 20 and the enclosure member 24 can be connected by means of screws (not shown) or any other locking components.

Please now refer to FIGS. 2B and 2C. According to the above structural design of the present invention, when the slim pump structure 2 operates, the working fluid 3 first flows from the water inlet 243 into the first chamber 2021. Then, the working fluid 3 will flow through the communication chamber 241 between the flow guide plate 22 and the enclosure member 24 into the flow way 214 of the rotor assembly 21. Then, the rotor assembly 21 will rotate to throw out the working fluid 3 to the second chamber 2022. Finally, the working fluid 3 will flow out from the water outlet 244 to complete an internal circulation. As aforesaid, the inner wall of the bearing hole 2031 is formed with multiple channels 2032. Therefore, when the working fluid 3 flows into the bearing hole 2031, the channels 2032 will employ the working fluid 3 as a medium to form a hydrodynamic bearing structure. Accordingly, the pump structure 2 can be slimmed and the total volume of the pump structure 2 can be minified. In addition, as aforesaid, multiple axial ribs 2051 are formed on the circumference of the cavity 205 at intervals and each two adjacent ribs 2051 define a gap 2052 therebetween to form a reinforcement structure. Under such circumstance, the thickness of the inner wall of the cavity 205 can be extremely thinned. In this case, the poles 232 of the stator assembly 23 and the magnetic member 25 disposed on the inner circumference of the rotor assembly 21 can get closer to each other. This greatly enhances the interaction and magnetization between the poles 232 and the magnetic member 25. Therefore, the operation efficiency of the rotor assembly 21 is enhanced so that the heat dissipation efficiency can be increased as a whole.

In conclusion, in comparison with the conventional pump structure, the present invention has the following advantages:
1. The pump structure of the present invention is slimmed.
2. The volume of the pump structure of the present invention is minified.
3. The heat dissipation efficiency of the pump structure of the present invention is greatly increased.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A slim pump structure comprising:
a case having a first side and a second side, the first side being formed with a pump chamber, a partitioning section partitioning the pump chamber into a first chamber and a second chamber, a pivotal section upward extending from the second chamber, a center of the pivotal section being formed with a bearing hole, the second side being recessed to form a cavity corresponding to the pivotal section, multiple axial ribs being formed on a circumference of the cavity at intervals, each two adjacent ribs defining a gap therebetween;
a rotor assembly received in the second chamber, the rotor assembly having a hub and a blade wheel, a rotary shaft downward extending from the hub, the rotary shaft being inserted in the bearing hole, a flow way being annularly formed on one side of the blade wheel, the flow way communicating with the first and second chambers;
a flow guide plate disposed on an outer circumference of the rotor assembly to cover the second chamber so as to uncommunicate the second chamber from the first chamber;
a stator assembly received in the cavity, the stator assembly having multiple poles respectively correspondingly received in the gaps; and
an enclosure member correspondingly disposed on the case to cover the case, the enclosure member and the flow guide plate defining therebetween a communication chamber in communication with the first chamber and the flow way.

2. The slim pump structure as claimed in claim 1, wherein the case further has a water inlet and a water outlet, the water inlet communicating with the first chamber, the water outlet communicating with the second chamber.

3. The slim pump structure as claimed in claim 1, wherein an inner wall of the bearing hole is formed with multiple axial channels in communication with the second chamber.

4. The slim pump structure as claimed in claim 1, wherein the flow guide plate has a top face and a bottom face, at least one raised body being formed on the top face to abut against the enclosure member, the bottom face covering the outer circumference of the rotor assembly.

5. The slim pump structure as claimed in claim 1, wherein a fitting section protrudes from the cavity corresponding to the bearing hole, the stator assembly being composed of multiple silicon steel sheets, a center of the stator assembly being formed with a perforation for correspondingly fitting on the fitting section.

6. The slim pump structure as claimed in claim 1, wherein the rotor assembly further has a magnetic member, the magnetic member being annularly disposed on an inner circumference of the rotor assembly.

7. The slim pump structure as claimed in claim 1, wherein a bearing is disposed in the bearing hole and the rotary shaft is passed through the bearing.

8. The slim pump structure as claimed in claim 1, wherein the case further has a stator cover, the stator cover being correspondingly disposed on an outer side of the stator assembly to cover the stator assembly, the stator cover being formed with an opening, a circuit board being connected with and disposed in the opening.

9. The slim pump structure as claimed in claim 2, wherein the second side of the case is formed with a receiving recess, the receiving recess being selectively formed on the second side of the case between the water inlet and the water outlet or along a periphery of the second side of the case.

10. The slim pump structure as claimed in claim 8, wherein the circuit board is a flexible printed circuit board.

11. The slim pump structure as claimed in claim 1, wherein the first side of the case is further formed with a locating groove along the outer circumference of the pump chamber, a leakproof member being correspondingly inlaid in the locating groove.

12. The slim pump structure as claimed in claim 1, wherein one end of the partitioning section is formed with a tongue section for providing flow guide effect, the tongue section and the partitioning section being integrally formed.

13. The slim pump structure as claimed in claim 2, wherein the water inlet and the water outlet have a flat form.

14. The slim pump structure as claimed in claim 1, wherein each rib has a continuous form or a discontinuous form and each rib has a cross section with a configuration of T-shape, semicircular shape or any other shape.
